(19) United States
(12) Patent Application Publication
(10) Pub. No.: US 2010/0276002 A1
(43) Pub. Date: Nov. 4, 2010

(54) PROCESS AND APPARATUS FOR PRODUCING POLYSILICON SHEETS

(76) Inventors: Nuofu Chen, Beijing (CN); Zhigang Yin, Beijing (CN); Shaolin Ruan, Jiangsu (CN); Zhengya Ruan, Jangsu (CN)

Correspondence Address: RENNER OTTO BOISSELLE & SKLAR, LLP, 1621 EUCLID AVENUE, NINETEENTH FLOOR, CLEVELAND, OH, 44115, US

(21) Appl. No.: 12/678,768

(22) PCT Filed: Sep. 22, 2008
(86) PCT No.: PCT/CN2008/001637

§ 371 Date: Jul. 15, 2010

(30) Foreign Application Priority Data
Sep. 20, 2007 (CN) 200710132054.3
Nov. 15, 2007 (CN) 200710135279.4

(51) Int. Cl. H01L 31/0256; C23C 16/02; C23C 16/44

(52) U.S. Cl. 136/261; 427/255.18; 118/725

(57) ABSTRACT

The present invention relates to a process for producing polysilicon wafer and a dual temperature field chemical vapor deposition apparatus for implementing the process. The process for producing polysilicon wafer is based on the formation of the polysilicon wafer through the reaction of trichlorosilane with hydrogen on the substrate. The dual temperature field chemical vapor deposition apparatus includes a reactor and a substrate, wherein the reactor has a closed space defined by a gas-feeding unit, a reaction heating furnace, a substrate heating furnace, and a substrate housing box, the gas-feeding unit is positioned on the reaction heating furnace and is contact with a water-cooling unit at the outer wall of the reaction heating furnace, the substrate heating furnace is positioned under the reaction heating furnace, the substrate moves along the gap between the reaction heating furnace and the substrate heating furnace.

The entire process for producing the polysilicon wafer of the present invention has many advantages that it involves simple equipment, low energy consumption and less material loss; the dual temperature field chemical vapor deposition apparatus, in comparison with the traditional chemical vapor deposition apparatus, has the advantage of being more versatile in its application along with its newly developed features.

### FIELD OF THE INVENTION

The present invention relates to the technology of producing polysilicon wafer, especially to a process for producing polysilicon wafer and a dual temperature field chemical vapor deposition apparatus for implementing the process.

### BACKGROUND OF THE INVENTION

Energy sources are the base materials for the existence and development of human society. Since the 18^{th} century, the system of energy sources based on coal, petroleum and natural gas has enormously pushed the human society forward. However, the serious consequences brought along with the wide application of fossil fuels including depletion of resources, environmental degradation, and evoke of political and economic dispute even conflicts and wars amongst countries and regions produce a serious threat to both the existence and development of human. To this end, development and utilization of new energy sources and renewable energy sources have become the very foundation of the living and breeding for the human future.

Sun is a gigantic nuclear reactor, which possesses not only the inexhaustible resources, but also the advantages of non-pollution and eco-friendly development and utilization, and which keeps transferring its enormous amounts of power to the earth. In this regard, development and utilization of solar energy would result in the achievement of a good society, good environment and economic efficiency. Under this circumstances, the United Nations hold meetings regarding the development and utilization of new energy sources and renewable energy sources, respectively, in Rome in 1961, in Nairobi, Kenya in 1981, in Brazil in 1992, in Harare, Zimbabwe in 1996, in which the development and utilization of solar energy was included in the schedule of development for the 21st century.

Solar cell makes use of the interaction of sunlight with materials in generating electric energy, which has been regarded as one of the most popular projects in the development and utilization of solar energy in large scale. The use of solar cell can solve the three problems regarding the supply of energy source in the development of human society: development of inexhaustible energy sources required in the cosmic space; acquisition of primary energy sources on the earth, so as to solve the problems of exhaustion of fossil fuel-based resources and environmental pollution currently encountered by the energy sources on the earth; supply of electricity at all times and places for the increasingly developed consumer electronics. Particularly, the use of solar cell does not release any gases like CO₂, which plays a significant role in improving the ecological environment and reducing the harmful effects of the greenhouse effect. With this understanding, solar cell is promising to become the most significant new energy source for the 21^{st} century. Some developed countries competitively increase their contribution for technologies and properties, in order to take possession of the increasingly expanded solar cell market.

Currently, the most widely used solar cell is a crystalline silicon cell, which will still take up the largest sector in the future market. Owing to the largest abundance of silicon reserve in the earth's crust, and that the process for producing crystalline silicon solar cell being the most sophisticated but relatively simple, a large-scale application of the crystalline silicon solar cell is promoted. However, the technology for producing the raw materials, i.e. the solar grade polysilicon for producing the crystalline silicon solar cell has become the bottleneck that constrains both the industrial development of crystalline silicon solar cell and the application of solar cell.

The chemical vapor deposition technology is widely utilized in the field of material preparation, which, in general, can be further divided into chemical vapor deposition (CVD) and metal organic chemical vapor deposition (MOCVD) depending on the use of different precursors for deposition. Chemical vapor deposition can be used to produce both of thin-film material and bulk material. For example, the Siemens process for producing silicon material of high purity indeed makes use of the chemical vapor deposition technology in producing a silicon bar of high purity, in which reduction reaction of trichlorosilane with hydrogen is taken place on a heated silicon bar.

Currently, the production procedure of the Siemens process for the solar grade polysilicon wafer is as follows:

(1) Metallurgical grade silicon+hydrogen chloride→trichlorosilane (Metallurgical grade purity: 3 N);

(2) Trichlorosilane (Metallurgical grade purity: 3N)→purifying→6 N;

(3) Trichlorosilane (6N)+hydrogen→chemical vapor deposition→solar grade silicon (6N);

(4) Smelting solar grade silicon (6N)→ingoting→solar grade polysilicon ingot;

(5) Solar grade polysilicon ingot→slicing→solar grade polysilicon wafer;

As reported, the procedure for obtaining polysilicon by reduction in the Siemens process consumes lots of electricity, and that the thus obtained polysilicon from the reduction process of the Siemens process must be once again subjected to smelting to give the polysilicon ingot by casting, which, again, consumes lots of electricity. Polysilicon ingot must be subjected to slicing to give the polysilicon wafer for producing solar cell, in which, at least one-third of the silicon material would be lost in the process of slicing. Consequently, the use of the Siemens process for producing polysilicon wafer is both energy and silicon material dissipation, which keeps the cost of the solar grade polysilicon always high, which, in turn, renders the polysilicon solar cell a high price. Such expensive polysilicon wafer adversely affect the application of polysilicon solar cell.

In addition, U.S. Pat. No. 4,981,102 discloses a reactor having a heated liner for producing silicon by chemical vapor deposition (CVD) and means for supplying a gas stream in the turbulent flow region. A gas stream including a silicon-containing compound is passed through a deposition chamber at turbulent flow rates for deposition of silicon on a non-reactive substrate liner heated above the decomposition temperature of the silicon-containing compound. Optionally, the liner is removable from the reactor for separation of deposited metal. Also optionally, the temperature of the liner in situ may be raised above the melting point of the deposited metal for melt out and recovery. However, this process is not suitable for the growth of heterojunction material, especially for the substrate material to be grown with relatively low temperature resistance but reacting at high reaction temperature.

A core heater positioned within the reactor is disclosed in the Chinese patent application (application no. 00810694.0; publication no. CN1364203A), in which a silicon core tube is positioned at the exterior of the heater, a heater is positioned in the interior of the silicon core tube, which is also regarded as a chemical vapor deposition via heating the substrate. Firstly, the silicon core tube is heated, and the heating of silicon gas is achieved by radical radiation from the core to the entire reaction chamber. Reactions are firstly occurred nearby the silicon core tube, and silicon not only deposits onto the silicon core tube, but also onto the middle tube.

In this regard, the chemical vapor deposition apparatus in the prior art involves substrate heating only, and there is a problem of insufficient deposition as reaction takes place on the substrate surface or around the substrate.

### SUMMARY OF THE INVENTION

The objective of the present invention is to provide a process for producing a polysilicon wafer for solar cell, which involves low energy consumption, high utilization of material and low production cost, and the process is particularly suitable for producing solar grade polysilicon wafer.

Another objective of the present invention is to provide a dual temperature field chemical vapor deposition apparatus capable of achieving homogeneous vapor deposition.

The process for producing a polysilicon wafer of the present invention comprises the following steps:

1) placing a substrate into a chemical vapor deposition apparatus after washing and removal of dirt and an oxide layer on the surface of the substrate;

2) evacuating the chemical vapor deposition apparatus at a vacuum level equal to or greater than 1×10⁻⁴Pa, followed by charging the chemical vapor deposition apparatus with hydrogen gas;

3) heating the chemical vapor deposition apparatus, wherein the reaction heating furnace is heated up to 1073K to 1473K, and the substrate heating furnace is heated up to 473K to 1273K;

4) charging the chemical vapor deposition apparatus with trichlorosilane and hydrogen gas when a stable temperature is achieved, and the following reaction is occurred:

SiHCl₃+H₂→Si+3HCl;

5) depositing silicon atoms generated from the above reaction on the substrate, and forming the polysilicon wafer;

6) withdrawing the feeding of trichlorosilane once the deposition is complete, while keeping charging hydrogen gas, and stopping heating;

7) stopping charging hydrogen gas when the temperature is reduced to room temperature, followed by nitrogen purging for 1 to 2 hours; and

8) shutting down vacuum pump and stopping nitrogen purging when the internal pressure of the chemical vapor deposition apparatus is the standard atmospheric pressure, and taking out the thus formed polysilicon wafer.

The substrate used in the process for producing polysilicon wafer according to the present invention can be a flexible substrate or a rigid substrate, and a flexible substrate is preferred. The flexible substrate is selected from the group consisting of stainless steel foil, copper foil, aluminum foil, or polymer film, or composite material composing of anyone of the above material with silicon. The rigid substrate is selected from glass, porcelain or silicon crystal. The purity of the silicon crystal used in the present invention may be lower than that of the silicon crystal used in the Siemens process.

In the process for producing polysilicon wafer of the present invention, the polymer used for the substrate is silica gel and/or polyvinyl material.

The polysilicon wafer produced by the process of the present invention is particularly suitable for use in solar cell.

In order to increase the quality of the obtained polysilicon wafer, the trichlorosilane preferably has a silicon purity of greater than 6N.

The present invention also provides a dual temperature field chemical vapor deposition apparatus for implementing the process of the present invention, the apparatus includes a reactor and a substrate, wherein the reactor has a closed space formed by a gas-feeding unit, a reaction heating furnace, a substrate heating furnace, and a substrate housing box. The gas-feeding unit is positioned above the reaction heating furnace and contacts with a water-cooling unit at the outer wall of the reaction heating furnace, while the substrate heating furnace is positioned under the reaction heating furnace, and the substrate moves along a gap between the reaction heating furnace and the substrate heating furnace.

Preferably, the heating apparatus in the reaction heating furnace of the present invention is a resistive heater. Positioning the heater near the inner wall of the reaction heating furnace can maintain the heating stability of the heater, and meanwhile efficiently control and stabilize the heating temperature of gases, allowing a stable and continuous reaction of gases to take place.

In the present invention, on the top of the reaction heating furnace is a gas-feeding unit, and at the bottom of the reaction heating furnace is a substrate that moving along the gap, which allows the produced gases heated up in the reaction heating furnace to reach the heated surface of the substrate for the deposition and to deposit.

In the present invention, a heating apparatus of the substrate heating furnace is preferably a resistive heater or induction heater positioned under the substrate. Both of the resistive heater and the induction heater have high heating efficiency, and the substrate can be heated homogenously.

In the present invention, the temperature control apparatus of the heating apparatus for both the reaction heating furnace and the substrate heating furnace are two independent apparatus, by which the heating temperature is controlled in the range from 273 to 1773K, and the temperature control accuracy is ±0.1K. At the time heating the chemical vapor deposition apparatus, the reaction heating furnace may be heated to 1073 K to 1473K, and the substrate heating furnace may be heated to 473K to 1273K.

In the present invention, the substrate moves along a gap between the reaction heating furnace and the substrate heating furnace, two ends of the substrate are positioned onto drums in the substrate housing box passing through tension pulleys, the substrate is made to move as the drum rotates, enabling a continuous deposition on the substrate. The temperature of the substrate is controlled by the substrate heating furnace, which allows a temperature lower than the reaction temperature, such that the substrate can be prevented from damage at elevated temperature.

The substrate in the reactor may be in the form of a discrete flake or a continuous tape.

The reactor inside may be in the shape of a cylinder, elliptical cylinder, sphere, ellipsoid, prism, or in a form with any combinations.

In the present invention, the wall of the vacuum reaction chamber is fabricated by stainless steel material or quartz material.

The dual temperature field chemical vapor deposition apparatus of the present invention not only can be used to implement the process for producing polysilicon wafer of the present invention, but also can be used for other chemical vapor deposition reactions, and thus in the dual temperature field chemical vapor deposition apparatus and its operation process of the present invention, the substrate material in the reactor, for example, can be silicon crystals, or stainless steel, aluminum foil, glass, porcelain or polymer, or composite material composing of anyone of the above material with silicon.

The beneficial effects of the present invention are that the entire process for producing polysilicon wafer of the present invention, in comparison with the traditional process that based on the Siemens process, involves simple equipments, low energy consumption and less material loss. Specifically, as the procedures of ingoting, ingot breaking and slicing are omitted in the process of the present invention, about 60% of electric energy and 50% of material are saved; area to weight ratio of the polysilicon wafer produced in the present invention is increased, and the polysilicon wafer possess excellent toughness, which renders the power to weight ratio of the thus prepared solar cell increased, and application to be more versatile.

The dual temperature field chemical vapor deposition apparatus of the present invention controls the substrate temperature using the substrate heating furnace, which allows a temperature lower than the reaction temperature, such that the substrate can be prevented from damage at elevated temperature. The dual temperature field chemical vapor deposition apparatus of the present invention, in comparison with the traditional chemical vapor deposition apparatus, has the advantage of being more versatile in its application along with more functions and newly developed features. The present invention allows the growth of material having higher reaction temperature on the substrate having relatively lower temperature-resistance, which facilitates the growth of heterojunction material.

### BRIEF DESCRIPTION OF THE DRAWINGS

FIG. 1 shows the structure of the dual temperature field chemical vapor deposition apparatus of the present invention.

Reference signs are specified as follows:

| | |
|---|---|
| 1. reaction heating furnace | 2. water-cooling apparatus |
| 3. resistive heater | 4. gas-feeding unit |
| 5. substrate heating furnace | 6. induction heater |
| 7. substrate | 8. substrate housing box |
| 9. tension pulley | 10. drum |

### PREFERRED EMBODIMENTS OF THE INVENTION

To further describe the principle and the structure of the present invention, the preferred embodiments of the present invention will now be described in detail with reference to the drawings.

Process for producing polysilicon wafer

The key equipments used: chemical vapor deposition apparatus, nitrogen generator (or nitrogen purification unit), hydrogen generator (or hydrogen purification unit), tail gas treating unit.

Trichlorosilane and hydrogen are used as the raw materials, of which the flow is controlled by a mass flow meter.

Production process:

1. Stainless foil tape substrate is placed into the chemical vapor deposition apparatus after subjecting to washing and corrosion treatment and removal of dirt and oxide layer on the surface;

2. The chemical vapor deposition apparatus is evacuated, in which the vacuum degree is up to 1×10⁻⁴Pa, the chemical vapor deposition apparatus is then charged with hydrogen; the above process is repeated for several times to minimize the residual air in the chemical vapor deposition apparatus;

3. The chemical vapor deposition apparatus is heated, in which the reaction heating furnace is heated to 1373K while the substrate heating furnace is heated to 1073K;

4. The chemical vapor deposition apparatus is then charged with trichlorosilane and hydrogen when a stable temperature is reached, in which the molecular ratio of trichlorosilane to hydrogen is 1:100, the following reaction is then occurred:

SiHCl₃+H₂→Si+3HCl;

5. Silicon atoms generated from the above reaction keep deposited on the stainless foil tape, which results in the formation of polysilicon wafer on stainless foil;

6. When the deposition is complete, feeding of trichlorosilane is stopped while hydrogen is kept charging in, and temperature is reduced;

7. When the temperature is reduced to room temperature, hydrogen charging is stopped, followed by nitrogen purging for 2 hours;

8. Vacuum pump is shut down, nitrogen purging is stopped when the internal pressure of the chemical vapor deposition apparatus raises to the standard atmospheric pressure, and the thus obtained stainless steel foil deposited with polysilicon wafer is then taken out.

9. Deposition is completed.

In accordance with the above process, a 20 micron thick polysilicon film is successfully deposited on the stainless steel foil substrate, resulting in the formation of the polysilicon sheet.

As shown in the following table, chemical vapor deposition of silicon can be taken place on various substrate material at different temperatures by the above process, resulting in the formation of the corresponding polysilicon wafer.

| | | Reaction heating | substrate heating |
|---|---|---|---|
| | | furnace | furnace |
| | substrate material | temperature/K | temperature/K |
| 1 | Silica gel | 1473 | 473 |
| 2 | Composite material of | 1273 | 1273 |
| | aluminium foil and silicon | | |
| 3 | Copper foil | 1373 | 973 |
| 4 | Glass | 1073 | 673 |

The dual temperature field chemical vapor deposition apparatus

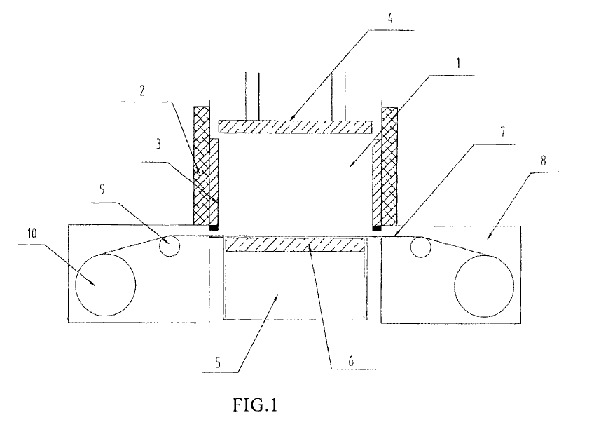

As shown in FIG. 1, stainless steel material is used for the fabrication of a cylindrical vacuum reaction chamber, of which the upper part is reaction heating furnace 1, water-cooling apparatus 2 is positioned near the outer wall of the reaction heating furnace, resistive heater 3 is positioned near the inner wall, a gas-feeding unit 4 is positioned on walls of reaction heating furnace 1, substrate heating furnace 5 is positioned under the opening of reaction heating furnace 1, the heating apparatus of substrate heating furnace 5 is induction heater 6, induction heater 6 and resistive heater 3 respectively possess an independent temperature-controlled apparatus, the two heating apparatuses control temperature is in the range from 273 to 1773K, and the temperature control accuracy is ±0.1K. Both sides of the furnaces are substrate housing boxes, both ends of substrate 7 are positioned onto drum 10 in substrate housing box 8, substrate moves along the gap between the two heating apparatuses after passing through tension pulley 9 in the substrate housing box, substrate 7 is made to move as drum 10 rotates, and a stable temperature of substrate 7 in the reaction chamber is maintained.

The dual temperature field chemical vapor deposition apparatus of the present invention is used to produce polysilicon film. Firstly, the dual temperature field chemical vapor deposition apparatus is evacuated, in which the vacuum degree is up to about 1×10⁻⁴Pa, the chemical vapor deposition apparatus is then charged with hydrogen. The above process may be repeated for several times to minimize the residual air in the chemical vapor deposition apparatus. The heating temperature of the heater for reaction heating furnace is controlled and maintained at 1373K. The heating temperature of the induction heater for substrate heating furnace is controlled and maintained at 1073K. The reaction chamber is then charged with trichlorosilane gas and hydrogen gas via the gas-feeding unit when a stable temperature is reached, silicon crystals generated from the reaction keep deposited on the moving stainless foil substrate.

The illustration above represents the preferred embodiment of the present invention provided for illustrative purposes only, and the protection scope of the present invention described herein should not be considered limited thereto. Indeed, various equivalent alternations and modifications of the invention made by those skilled in the art under the technical inspiration provided in the present invention are intended to fall within the scope of the present invention.

1. A process for producing a polysilicon wafer, wherein the process comprises the following steps of:
1) placing a substrate into a chemical vapor deposition apparatus after washing and removal of dirt and an oxide layer on the surface of the substrate;
2) evacuating the chemical vapor deposition apparatus at a vacuum level equal to or greater than 1×10⁻⁴Pa, followed by charging the chemical vapor deposition apparatus with hydrogen gas;
3) heating the chemical vapor deposition apparatus, wherein the reaction heating furnace is heated up to 1073K to 1473K, and the substrate heating furnace is heated up to 473K to 1273K;
4) charging the chemical vapor deposition apparatus with trichlorosilane and hydrogen gas when a stable temperature is achieved, and the following reaction is occurred:
SiHCl₃+H₂→Si+3HCl;
5) depositing silicon atoms generated from the above reaction on the substrate, and forming the polysilicon wafer;
6) withdrawing the feeding of trichlorosilane once the deposition is complete, while keeping charging hydrogen gas, and stopping heating;
7) stopping charging hydrogen gas when the temperature is reduced to room temperature, followed by nitrogen purging for 1 to 2 hours; and
8) shutting down vacuum pump and stopping nitrogen purging when the internal pressure of the chemical vapor deposition apparatus is the standard atmospheric pressure, and taking out the thus formed polysilicon wafer.

2. The process of claim 1, wherein the substrate is a flexible substrate or a rigid substrate.

3. The process of claim 2, wherein the flexible substrate is selected from the group consisting of stainless steel foil, copper foil, aluminum foil, or polymer film, or composite material composing of anyone of the above material with silicon.

4. The process of claim 3, wherein the polymer is silica gel and/or polyvinyl material.

5. The process of claim 2, wherein the rigid substrate is selected from glass, porcelain or silicon crystal.

6. The process of claim 1, wherein the trichlorosilane has a silicon purity of 6N or higher.

7. A solar cell comprising a polysilicon wafer produced by the process of claim 1.

8. A dual temperature field chemical vapor deposition apparatus for implementing the process of claim 1, comprising a reactor and a substrate, wherein the reactor comprises a closed space formed by a gas-feeding unit, a reaction heating furnace, a substrate heating furnace and a substrate housing box, wherein the gas-feeding unit is positioned above the reaction heating furnace and contacts with a water-cooling unit at the outer wall of the reaction heating furnace, the substrate heating furnace is positioned under the reaction heating furnace, and the substrate moves along a gap between the reaction heating furnace and the substrate heating furnace.

9. The apparatus of claim 8, wherein a heating apparatus in the reaction heating furnace is a resistive heater positioned near the inner wall of the reaction heating furnace.

10. The apparatus of claim 8, wherein on the top of the reaction heating furnace is the gas-feeding unit, and at the bottom of the reaction heating furnace is the moving substrate.

11. The apparatus of claim 8, wherein a heating apparatus in the substrate heating furnace is a resistive heater or induction heater positioned under the substrate.

12. The apparatus of claim 8, wherein both ends of the substrate are positioned onto drums in the substrate housing box passing through tension pulleys.
